(19) United States
(12) Patent Application Publication
(10) Pub. No.: US 2021/0144840 A1
(43) Pub. Date: May 13, 2021

(54) HEAT SPREADERS FOR SEMICONDUCTOR DEVICE MODULES

(71) Applicant: Micron Technology, Inc., Boise, ID (US)

(72) Inventor: George E. Pax, Lake City, FL (US)

(21) Appl. No.: 16/681,350

(22) Filed: Nov. 12, 2019

(51) Int. Cl. H05K 1/02; H05K 1/11; H05K 1/18

(52) U.S. Cl. CPC H05K 1/0203; H05K 1/117; H05K 2201/10393; H05K 2201/10522; H05K 2201/10159; H05K 1/181

(57) ABSTRACT

A heat spreader configured for use with a dual-in line memory module (DIMM) is provided. The heat spreader comprises a thermally conductive body having upper and lower edges with a first length, opposing side edges with a second length less than the first length, and a planar surface configured for attachment to a plurality of co-planar semiconductor devices of the DIMM, and a retaining clip configured to releasably attach the thermally conductive body to the DIMM when disposed within a side notch of the DIMM and around a first one of the opposing side edges of the thermally conductive body.

### TECHNICAL FIELD

The present disclosure generally relates to semiconductor devices, and more particularly relates to heat spreaders for semiconductor device modules.

### BACKGROUND

Memory packages or modules typically include multiple memory devices mounted on a substrate. Memory devices are widely used to store information related to various electronic devices such as computers, wireless communication devices, cameras, digital displays, and the like. Information is stored by programing different states of a memory cell. Various types of memory devices exist, including magnetic hard disks, random access memory (RAM), read only memory (ROM), dynamic RAM (DRAM), synchronous dynamic RAM (SDRAM), and others.

Improving memory packages, generally, may include increasing memory cell density, increasing read/write speeds or otherwise reducing operational latency, increasing reliability, increasing data retention, reducing power consumption, reducing manufacturing costs, and reducing the size or footprint of the memory packages and/or components of the memory devices, among other metrics. A challenge associated with improving memory packages is that improvements often result in increased heat generation—e.g., as a result of increasing memory device density, increasing the speed or processing ability of the memory devices, etc. Without sufficient cooling, the additional heating can cause the memory devices to reach temperatures above their maximum operating temperatures (Tₘₐₓ).

### BRIEF DESCRIPTION OF THE DRAWINGS

FIGS. 1 and 2 illustrate a memory module without and with a traditional heat spreader.

FIG. 3 illustrates a simplified partial schematic view of a memory module modified to accept an improved heat spreader in accordance with one embodiment of the present disclosure.

FIGS. 4 and 5 illustrate a simplified partial schematic view of a memory module with an attached improved heat spreader in accordance with one embodiment of the present disclosure.

### DETAILED DESCRIPTION

Specific details of several embodiments of memory modules having heat spreaders, and associated systems and methods, are described below with reference to the appended Figures. In several of the embodiments, a heat spreader configured for use with a dual-in line memory module (DIMM), comprises a thermally conductive body having upper and lower edges with a first length, opposing side edges with a second length less than the first length, and a planar surface configured for attachment to a plurality of co-planar semiconductor devices of the DIMM; and a retaining clip configured to releasably attach the thermally conductive body to the DIMM when disposed within a side notch of the DIMM and around a first one of the opposing side edges of the thermally conductive body.

FIGS. 1 and 2 illustrate a dual-in line memory module (DIMM) without and with a traditional heat spreader. As can be seen with reference to FIG. 1, DIMM 100 includes a substrate 101, an edge connector 102 along a bottom edge of the substrate 101, and one or more notches 103 in opposing ends 104 that are perpendicular to the bottom edge of the substrate 101. DIMM 100 can further include multiple semiconductor devices on one or both faces of the substrate 101, such as memory devices 105 and register clock driver (RCD) 106. In operation, memory devices 105 and RCD 106 can generate waste heat, which can negatively impact the operation of DIMM 100 if left unaddressed. Accordingly, DIMM 100 can be configured with a heat spreader on one or both faces of DIMM 100 (e.g., on whichever face of DIMM 100 semiconductor devices are provided), such as heat spreader 210 illustrated in FIG. 2. As shown in FIG. 2, heat spreader 210 can be attached to the DIMM 100 with one or more clips 211, which provide spring tension to hold the substantially planar body of the heat spreader 210 in contact with the co-planar surfaces of the semiconductor devices of the DIMM 100, to facilitate heat sinking and thermal radiation and convection away from the DIMM 100. It has been common practice to have notches in the top edge of the substrate 101 so that the clips do not increase the overall height of the DIMM 100. Placing notches along the top edge of the substrate 101 reduces the area available for memory components which can limit the physical size of the memory component that will fit. It may also limit the physical size of the spreader 210 which would have similar notches or a reduced height over the full spreader 210 length.

One drawback of this approach arises in a system utilizing multiple memory modules such as DIMM 100. In such a system, memory modules be spaced apart by a predetermined pitch (e.g., of about 10 mm for DDR4 modules, or about 7.6 mm for DDR5 modules). Accordingly, the space available between adjacent memory modules for the heat spreaders and clips is about equal to this pitch minus the thickness of one of the memory modules (e.g., with a distance between outer surfaces of opposing memory devices of a memory module being about 2.8 mm, the gap between devices without heat spreaders is about 7.2 mm for DDR4 modules, and less than 5 mm for DDR5 modules). This gap is not consistent along the height and length of a module, however. In this regard, memory modules are generally attached to a host device by latches on side posts, with the latches engaging one or more of the notches 103 in the ends 104 of the DIMM 100. Accordingly, the lower portion of the gap between adjacent modules can be substantially blocked by the latches and side posts. Accordingly, the gap between upper portion of adjacent modules is where much of the heat dissipation from a heat spreader to a cooling airflow occurs. Obstructing part or all of this gap between the upper portions of adjacent modules with top-mounted clips, such as clip 211 in FIG. 2, can significantly impact the thermal performance of the system for the worse.

To address the foregoing problems, embodiments of the present disclosure can provide heat spreaders for semiconductor device modules to provide improved performance in memory systems with reduced spacing between adjacent memory modules. For example, FIG. 3 illustrates a simplified partial schematic view of a dual-in line memory module (DIMM) 300 modified to accept an improved heat spreader in accordance with one embodiment of the present disclosure. Like DIMM 100, DIMM 300 includes a substrate 301, an edge connector 302 along a bottom edge of the substrate 301, multiple semiconductor devices on one or both faces of the substrate 301, such as memory devices 305 and register clock driver (RCD) 306, and one or more notches 303 in opposing ends 304 (e.g., those ends that are perpendicular to the bottom edge of the substrate 301). To accommodate a retaining clip (described in greater detail below with respect to FIG. 4) for attaching one or more heat spreaders to the DIMM 300, the one or more notches 303 can have a greater depth than the notches 103 of the traditional DIMM. In this regard, the notches 103 of DIMM 100 may have a depth of about 2.5 mm to accommodate the latches of the side posts of a host device. To accommodate a heat spreader with a thickness of about 1 mm in the notch region, the notches 303 of DIMM 300 may be about 1 mm deeper, and accordingly have a depth of about 3.5 mm.

This may be better understood with reference to FIGS. 4 and 5, which illustrate a simplified partial schematic view of DIMM 300 with an attached improved heat spreader 410 in accordance with one embodiment of the present disclosure. As can be seen with reference to FIGS. 4 and 5, heat spreader 410, like heat spreader 210, has a planar body held in contact with the co-planar surfaces of the semiconductor devices of the DIMM 300, to facilitate heat sinking and thermal radiation and convection away from the DIMM 300. Unlike heat spreader 210, however, heat spreader 410 is attached by retaining clips 411 which mount not around a top edge of the DIMM 300, but around the ends 304 by engaging one or more of the notches 303 in each end 304. Retaining clips 411 may comprise stainless steel or other suitable metals that may be used as springs and meet the environmental requirements. Retaining clips 411 provide spring tension to hold the substantially planar body of the heat spreader 410 in contact with the co-planar surfaces of the semiconductor devices of the DIMM 300, to facilitate heat sinking and thermal radiation and convection away from the DIMM 300. In this regard, although not illustrated, a layer of thermal interface material may be disposed on the planar surface of the heat spreader 210 facing the semiconductor devices of DIMM 300 to fill voids between the planar surface and the plurality of co-planar semiconductor devices.

According to one aspect of the present disclosure, although installation of the retaining clips 411 in the notches 303 cause the retaining clips 411 to use a portion of the depth of the notches 303, the notches 303 have a depth greater than the notches 103 of the traditional DIMM 100, such that they still provide adequate depth for engagement with the latch of a side post of a host device (e.g., still have a usable depth of about 2.5 mm for engaging with the latch). To facilitate attachment of the retaining clip 411 to the DIMM 300, the notches 303 may have a height equal to or greater than a width of the retaining clip 411. For example, the notches of a DDR5 DIMM may have a height of about 3 mm, and the retaining clips 411 accordingly may have a width of less than or equal to 3 mm.

According to one aspect of the present disclosure, providing end-mounted clips 411 in one or more notches 303 of the DIMM 300, the region between upper portion of adjacent DIMMs remains relatively unobstructed when compared to the traditional DIMM arrangements of FIGS. 1 and 2, allowing for improved airflow (e.g., provided by a fan or the like) and accordingly improved thermal performance.

Although in the foregoing example embodiments, heat spreaders have been described and illustrated with retaining clips at each opposing end of a DIMM, in other embodiments, heat spreaders may be provided with one or more retaining clips at only a single end of a DIMM. Moreover, although in the foregoing example embodiments, heat spreaders have been described and illustrated as being provided on both opposing faces of a DIMM, in other embodiments (e.g., embodiments in which semiconductor devices are provided on only a single face of a DIMM), heat spreaders may be provided on only a single face of a DIMM. Further, although in the foregoing example embodiments, heat spreaders have been described and illustrated as including only a single retaining clip on an end of the DIMM engaging with a single notch thereof, in other embodiments multiple retaining clips may be provided on the same end of a DIMM, each in engaging in a different notch thereof.

Although in the foregoing example embodiments, retaining clips have been described and illustrated as each engaging with a single notch in the end of a DIMM, in other embodiments, retaining clips may be provided that engage with more than one notch in the end of a DIMM. In such an embodiment, one or more of the utilized notches may be modified with an increased depth to offset the loss of useable depth for a latch on a side post. Moreover, although in the foregoing example embodiments, retaining clips have been described and illustrated as extending horizontally inwards from a notch with a continuous width, in other embodiments retaining clips with different profiles of varying width or extending in different directions (e.g., diagonally, vertically, etc.) may be provided.

Although in the foregoing example embodiments, DIMMs have been described and illustrated as including two notches in each end thereof, in other embodiments DIMMs may be provided with different numbers of notches (e.g., one notch, three notches, four notches, etc.), and may either have the same number of notches on each end (e.g., as is illustrated and described above), or a different number of notches on each end (e.g., including zero notches on one end). Moreover, although in the foregoing example embodiments, retaining clips have been described and illustrated as relying upon spring tension to attach the thermally conductive body of a heat spreader to the semiconductor devices of a DIMM, retainer clips utilizing other attachment methods (e.g., pins, latches, cams, etc.) may also be used.

In accordance with various embodiments of the present disclosure, the thermally conductive body of the heat spreader 410 can be formed from a metal or another thermally conductive material (e.g., copper, aluminum, alloys thereof, graphite, thermally-conductive polymers, etc.). Although in the foregoing example embodiments heat spreaders have been illustrated as solid monolithic thermally conductive bodies, in other embodiments of the present disclosure, heat spreaders with other configurations can be provided. For example, heat spreaders with internal cooling channels, external radiating fins or other surface area-increasing features may also be provided.

Numerous specific details are discussed to provide a thorough and enabling description of embodiments of the present technology. A person skilled in the art, however, will understand that the technology may have additional embodiments and that the technology may be practiced without several of the details of the embodiments described below with reference to the appended Figures. In other instances, well-known structures or operations often associated with memory devices are not shown, or are not described in detail, to avoid obscuring other aspects of the technology. In general, it should be understood that various other devices and systems in addition to those specific embodiments disclosed herein may be within the scope of the present technology. For example, in the illustrated embodiments, the memory devices and systems are primarily described in the context of DIMMs compatible with DRAM and flash (e.g., NAND and/or NOR) storage media. Memory devices and systems configured in accordance with other embodiments of the present technology, however, can include memory modules compatible with other types of storage media, including PCM, RRAM, MRAM, read only memory (ROM), erasable programmable ROM (EPROM), electrically erasable programmable ROM (EEROM), ferroelectric, magnetoresistive, and other storage media, including static random-access memory (SRAM). Additionally, at least some of the heat spreaders described herein may be useful in semiconductor packages other than memory packages.

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the technology have been described herein for purposes of illustration, but that various modifications may be made without deviating from the disclosure. Accordingly, the invention is not limited except as by the appended claims. Furthermore, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

1. A heat spreader configured for use with a dual-in line memory module (DIMM), comprising:
a thermally conductive body having upper and lower edges with a first length, opposing side edges with a second length less than the first length, and a planar surface configured for attachment to a plurality of co-planar semiconductor devices of the DIMM; and
a retaining clip configured to releasably attach the thermally conductive body to the DIMM when disposed within a side notch of the DIMM and around a first one of the opposing side edges of the thermally conductive body.

2. The heat spreader of claim 1, wherein the thermally conductive body is a first thermally conductive body, the plurality of co-planar semiconductor devices of the DIMM is a first plurality of co-planar semiconductor devices of the DIMM, and further comprising:
a second thermally conductive body having upper and lower edges with the first length, opposing side edges with the second length, and a planar surface configured for attachment to a second plurality of co-planar semiconductor devices of the DIMM,
wherein the second plurality of co-planar semiconductor devices of the DIMM are on an opposing face of the DIMM from the first plurality of co-planar semiconductor devices of the DIMM.

3. The heat spreader of claim 1, wherein the retaining clip is a first retaining clip, the side notch of the DIMM is a first side notch of the DIMM, and further comprising:
a second retaining clip configured to releasably attach the thermally conductive body to the DIMM when disposed within a second side notch of the DIMM and around a second one of the opposing side edges of the thermally conductive body,
wherein the second side notch of the DIMM is on an opposing edge of the DIMM from the first side notch of the DIMM.

4. The heat spreader of claim 1, further comprising:
a layer of thermal interface material disposed on the planar surface and configured to fill voids between the planar surface and the plurality of co-planar semiconductor devices.

5. The heat spreader of claim 1, wherein the DIMM is a DDR5 DRAM memory module.

6. The heat spreader of claim 1, wherein the thermally conductive body comprises copper, aluminum, a combination thereof, or an alloy thereof.

7. The heat spreader of claim 1, wherein the retaining clip comprises stainless steel.

8. A dual-in line memory module (DIMM), comprising:
a substrate having an edge connector along a bottom edge of the substrate and opposing ends perpendicular to the bottom edge, each of the opposing ends including at least one side notch;
a first plurality of co-planar semiconductor devices on a first face of the DIMM;
a thermally conductive body having upper and lower edges with a first length, opposing side edges with a second length less than the first length, and a planar surface configured for attachment to the plurality of co-planar semiconductor devices,
a retaining clip configured to releasably attach the thermally conductive body to the plurality of co-planar semiconductor devices when disposed within one of the at least one side notch of the substrate and around a first one of the opposing side edges of the thermally conductive body.

9. The DIMM of claim 8, wherein the thermally conductive body is a first thermally conductive body, and further comprising:
a second thermally conductive body having upper and lower edges with the first length, opposing side edges with the second length, and a planar surface configured for attachment to a second plurality of co-planar semiconductor devices of the DIMM,
wherein the second plurality of co-planar semiconductor devices of the DIMM are on a second face of the DIMM opposing the first face.

10. The DIMM of claim 8, wherein the retaining clip is a first retaining clip, and further comprising:
a second retaining clip configured to releasably attach the thermally conductive body to the DIMM when disposed within another one of the least one side notches of the substrate around a second one of the opposing side edges of the thermally conductive body.

11. The DIMM of claim 8, further comprising:
a layer of thermal interface material disposed on the planar surface and configured to fill voids between the planar surface and the first plurality of co-planar semiconductor devices.

12. The DIMM of claim 8, wherein the DIMM is a DDR5 DRAM memory module.

13. The DIMM of claim 8, wherein the thermally conductive body comprises copper, aluminum, a combination thereof, or an alloy thereof.

14. The DIMM of claim 8, wherein the at least one side notch extends inwardly at least 3.5 mm from the end of the substrate.

15. The DIMM of claim 8, wherein the retaining clip has a thickness of less than or equal to 1 mm in a portion thereof disposed within the one of the at least one side notch.

16. The DIMM of claim 8, wherein the at least one side notch has a height of at least 3 mm.

17. The DIMM of claim 15, wherein the retaining clip has a height of less than or equal to 3 mm.

18. The DIMM of claim 8, wherein the retaining clip comprises stainless steel.

19. The DIMM of claim 8, wherein the retaining clip does not extend above a level of the one of the at least one side notch.

20. The DIMM of claim 8, wherein the thermally conductive body further comprises surface-area increasing features on a surface opposite the planar surface.
